(19) United States
(12) Patent Application Publication
(10) Pub. No.: US 2007/0064486 A1
(43) Pub. Date: Mar. 22, 2007

(54) Display device and fabricating method thereof

(76) Inventors: Un-cheol Sung, Gyeonggi-do (KR); Beohm-rock Choi, Seoul (KR)

Correspondence Address: MACPHERSON KWOK CHEN & HEID LLP, 2033 GATEWAY PLACE, SUITE 400, SAN JOSE, CA, 95110, US

(21) Appl. No.: 11/525,273

(22) Filed: Sep. 21, 2006

(30) Foreign Application Priority Data
Sep. 22, 2005 (KR) 2005-0088157

(51) Int. Cl. G11C 16/04

(52) U.S. Cl. 365/185.13

(57) ABSTRACT

A display device that lends itself to a cost-effective and simplified manufacturing process is presented. The display device includes an insulating substrate; a common voltage line formed on the insulating substrate; an insulating layer provided on the common voltage line; and a contact hole extending through the insulating layer to the common voltage line. A deposition preventing column contacts the common voltage line at the bottom of the contact hole. The deposition preventing column has a width that changes with distance from the insulating substrate and covers the common voltage line. A common electrode is connected to the common voltage line.

### CROSS-REFERENCE TO RELATED APPLICATIONS

This application claims the benefit of Korean Patent Application No. 2005-0088157 filed on Sep. 22, 2005 in the Korean Intellectual Property Office, the disclosure of which is incorporated herein by reference.

### BACKGROUND OF THE INVENTION

1. Field of the Invention

The present invention relates to a display device, and more particularly to a top-emission type display device.

2. Description of the Related Art

Among the different types of flat panel displays in the market, organic light emitting diode (OLED) has recently been attracting particular attention because of its desirable characteristics such as low driving voltage, thinness, light weight, wide view angle, and a relatively short response time. In an OLED, a plurality of thin film transistors is provided on an OLED substrate. A pixel electrode for a pixel and a pixel electrode for a reference voltage are provided on the thin film transistors. When voltage is applied to the two electrodes, holes and electrons are combined to form excitons in an emission layer positioned between the electrodes. Light is emitted when the exciton transitions back to the ground state. The OLED controls the light emission to display a desired image.

OLED is classified into a top emission type and a bottom emission type according to which surface is the primary light-emitting surface. In the case of the top emission type OLED, light exits the OLED through a transparent conductive metal that is deposited on an entire surface of the OLED and used as a common electrode. Because this common electrode, which is generally made of indium tin oxide (ITO) or indium zinc oxide (IZO), has high resistance, a common voltage is not sufficiently applied to the substrate. Therefore, the OLED includes an auxiliary common electrode to compensate for any insufficiency in the common voltage. In the case where a wiring metal layer is formed as the auxiliary common electrode on the substrate, a plurality of contact holes is needed to connect the auxiliary common electrode with the common electrode. In the OLED, an entire surface deposition method using an open mask can be applied to an organic layer such as a hole injection layer and an electron transport layer. One exception is that the emission layer, which should be deposited separately according to light emission colors. However, at this time, a problem arises in that an organic layer is deposited in the contact hole needed for connection between the common electrode and the auxiliary common electrode. Therefore, a shadow mask is needed even when the organic layer is deposited, complicating the fabricating process and increasing the production cost.

### SUMMARY OF THE INVENTION

Accordingly, it is an aspect of the present invention to provide a display device that can be made with a simplified fabricating process.

The present invention includes a display device that has an insulating substrate; a common voltage line formed on the insulating substrate; an insulating layer provided on the common voltage line; a contact hole extending through the insulating layer to the common voltage line; and a deposition preventing column contacting a portion of the common voltage line in the contact hole. The deposition preventing column has a width that changes with distance from the insulating substrate. A common electrode is connected to the common voltage line.

In another aspect, the present invention is a method of fabricating a display device. The method entails forming a common voltage line on an insulating substrate; forming an insulating layer on the common voltage line; forming a contact hole through the insulating layer, wherein the contact hole extends to the common voltage line; and forming an deposition preventing column that contacts a portion of the exposed common voltage line. The deposition preventing column has a width that changes with distance from the insulating substrate. A common electrode connected to the common voltage line is formed.

### BRIEF DESCRIPTION OF THE DRAWINGS

The above and/or other aspects and advantages of the present invention will become apparent and more readily appreciated from the following description of the embodiments taken in conjunction with the accompany drawings, of which:

FIG. 1 is a plan view of a display device according to a first embodiment of the present invention;

FIG. 2 is a sectional view of the display device, taken along line II-II of FIG. 1;

FIGS. 3A through 3H illustrating a process of fabricating the display device according to the first embodiment of the present invention;

FIG. 4 is a sectional view of a display device according to a second embodiment of the present invention; and

FIG. 5 is a sectional view of a display device according to a third embodiment of the present invention.

### DETAILED DESCRIPTION OF THE EMBODIMENTS

Hereinafter, embodiments of the present invention will be described with reference to accompanying drawings, wherein like numerals refer to like elements and repetitive descriptions will be avoided as necessary. Further, although OLED is described as an exemplary embodiment of a display device, this is not a limitation of the invention. Also, the present invention can be applied to various devices that use selective material deposition using an open mask.

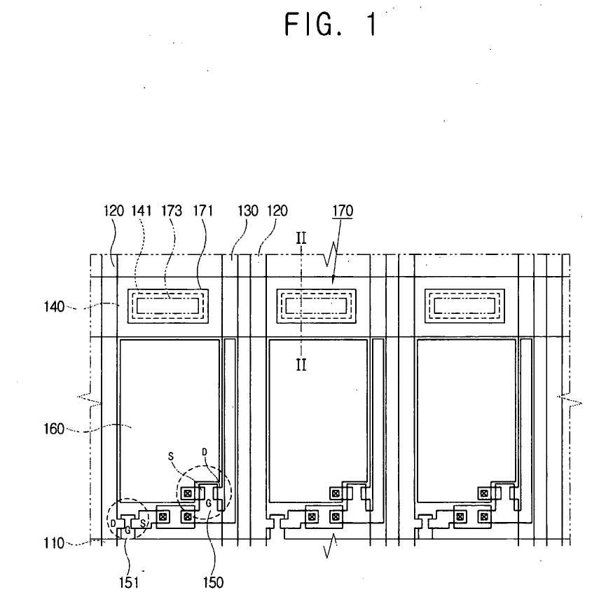

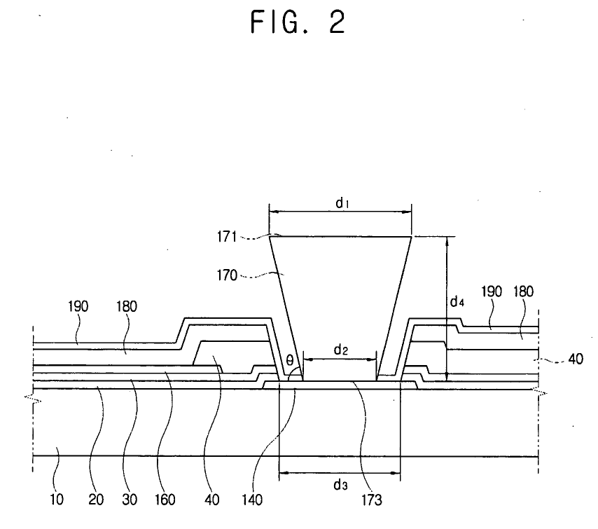

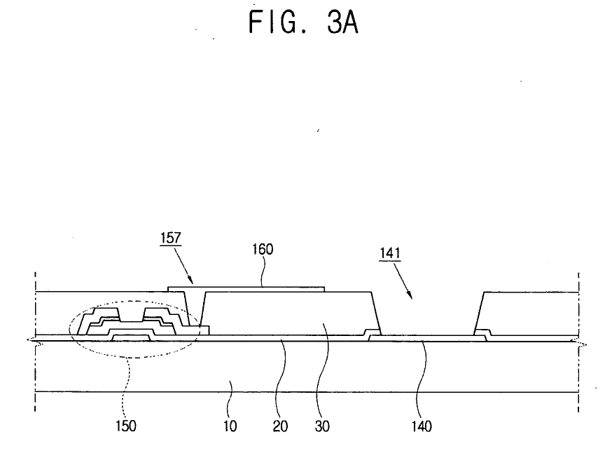

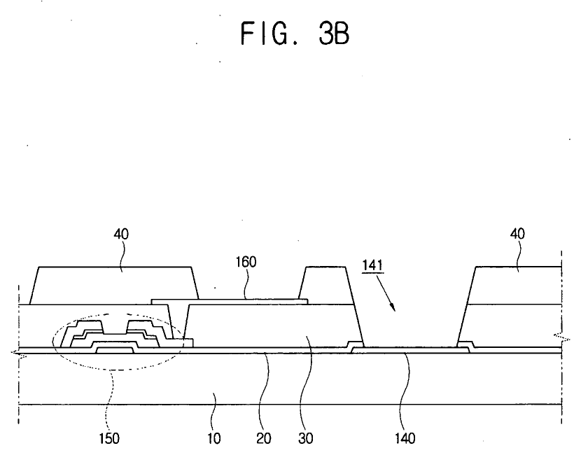

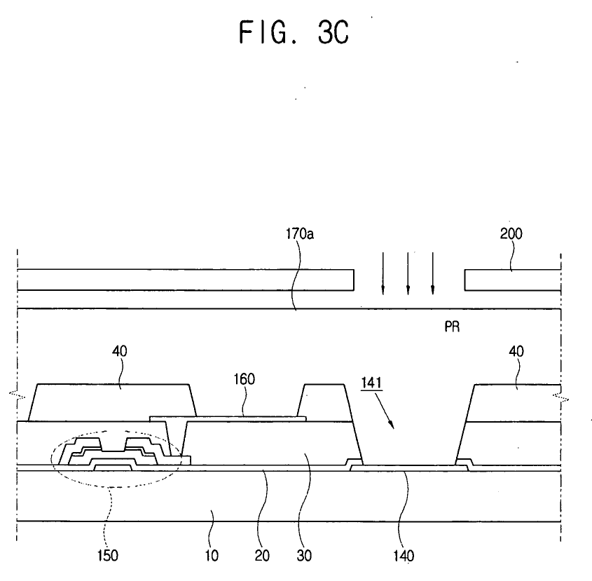

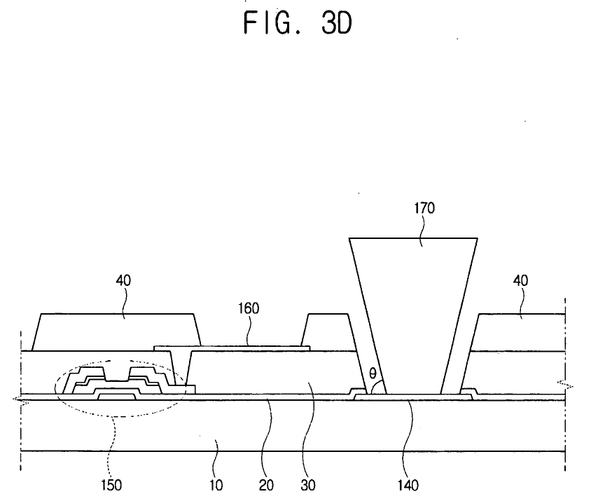

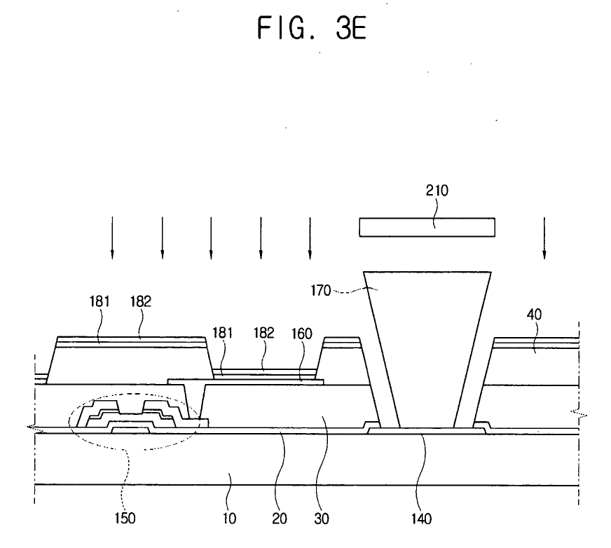

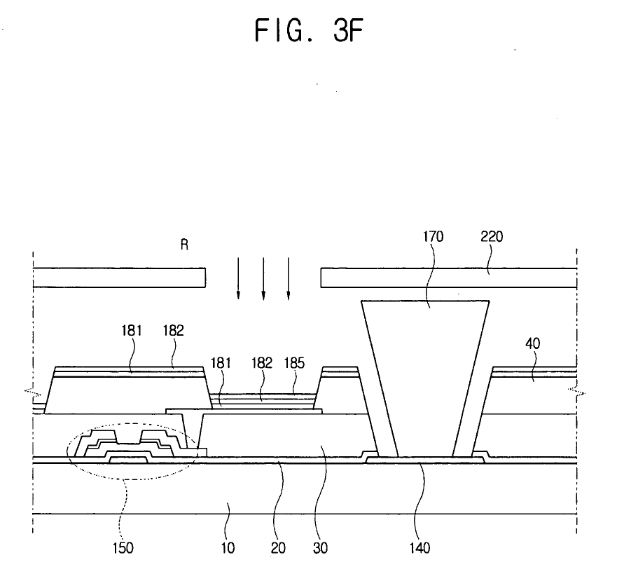

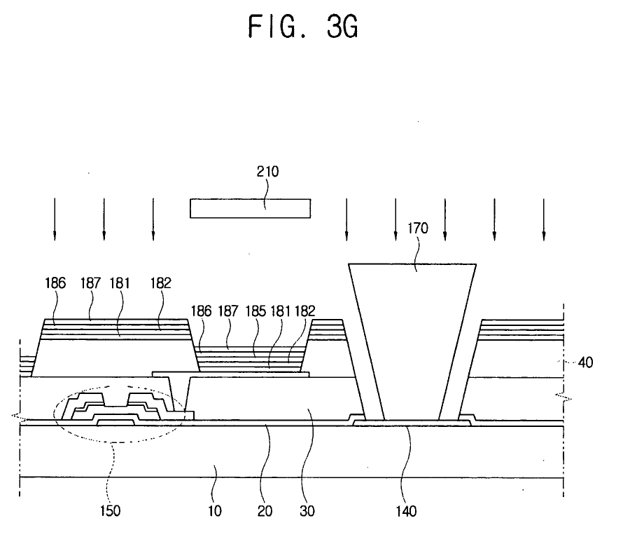

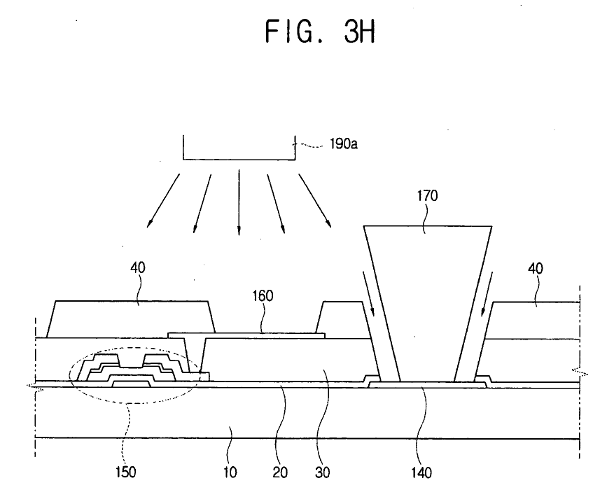

A display device according to a first embodiment of the present invention will be described with reference to FIGS. 1 through 3. FIG. 1 is a plan view of a display device according to the first embodiment of the present invention; FIG. 2 is a sectional view of the display device, taken along line II-II of FIG. 1; and FIGS. 3A through 3H illustrating a process of fabricating the display device according to the first embodiment of the present invention.

As shown, a display device includes a gate line 110, a data line 120, a driving voltage line 130, and a common voltage line 140. Where the gate line 110 and the data line 130 overlap, a switching transistor 141 is formed and electrically connected to both the gate and data lines 110 and 120. A pixel is defined by the gate line 110, the data line 120 and the driving voltage line 130, and a pixel electrode 160 is formed and electrically and physically connected with a driving thin film transistor 150 through a contact hole. Here, the driving thin film transistor 150 is connected with the driving voltage line 130. Further, the display device includes a deposition preventing column 170 formed in the contact hole 141 that partially exposes the common voltage line 140.

The gate lines 110 are formed parallel to one another on an insulating substrate 10, and extend substantially perpendicularly to the data lines 120 and the driving voltage lines 130, thereby forming the pixels. A gate metal layer, which is formed into the gate line 110 and gate electrodes G of the driving and the switching transistors 150 and 151, can be formed as a single layer or multiple layers. The gate line 110 applies a gate on/off voltage to the switching transistor 151.

The common voltage line 140 is formed to extend parallel to the gate line 110, and the common voltage line 140 is generally formed while the gate line 110 is patterned. Although the common voltage line 140 may be formed from the same layer as the gate line 110, it is not necessary to make the common voltage line 140 of the same metal material as the gate line 110. In some embodiments, the common voltage line 140 is formed to extend parallel to the data line 120 or the driving voltage line 130. In these embodiments, the common voltage line 140 may be made of the same material as the data line 120. Further, even in the case where the common voltage line 140 extends parallel to the gate line 110, the common voltage line 140 can be made of the same material as the data line 120. In this case, the common voltage line 140 is patterned separately from other data wiring lines 120 and 130.

The deposition preventing column 170 is formed in the contact hole 141 to contact the common voltage line 140 at the bottom of the contact hole 141. Here, the deposition preventing column 170 is provided to prevent an organic emission layer 180 from covering the exposed common voltage line 140. In the case where the organic layer of each pixel is formed by the open mask having no detailed pattern, the contact hole 141 exposing the common voltage line 140 is likely to be filled with the organic emission layer. Deposition of the organic emission layer 180 in the contact hole 141 is undesirable as it interferes with the common voltage line 140 making a connection with another electrically conductive part of the device. Thus, the deposition preventing column 170 is used for preventing the contact hole 141 from being filled with the organic layer.

The gate metal layer is covered with a gate insulating layer 20 including silicon nitride (SiNₓ) or the like. The gate insulating layer 20 electrically insulates the gate metal layer from the data metal layer.

The data line 120 and the data metal layer including drain and source electrodes D and S of the switching and driving transistors 151 and 150 are insulated from the gate metal layer. Through the data line 120, the data voltage is applied to the switching transistor 151.

The driving voltage line 130 extends parallel to the data line 120 and substantially perpendicularly to the gate line 110, thereby forming pixels in a matrix. In general, the driving voltage line 130 is formed from the data metal layer, same as the data line 120. The driving voltage line 130 applies a driving voltage of a uniform level to the driving transistor 150.

One driving voltage line 130 can be provided per pixel, although this is not a limitation of the invention. In some embodiments, one driving voltage line 130 may be shared between two pixels such that two adjacent pixels receive the driving voltage through one driving voltage line 130. In this structure, the fabricating process is simplified as the driving voltage lines are reduced. Further, there is less electromagnetic interference (EMI) because there are fewer driving voltage lines.

The switching transistor 151 receives a gate on/off voltage through the gate electrode G. The gate electrode G branches from the gate line 110 (see FIG. 1) and transmits the data voltage of the data line 120 from the drain electrode D to the source electrode S. Here, the source electrode S of the switching transistor 151 is electrically connected to the gate electrode G of the driving transistor 150 through the contact hole.

The driving transistor 150 controls the current between the drain and source electrodes D and S based on the data voltage applied to the gate electrode G. The voltage applied to the pixel electrode 160 through the source electrode S corresponds to the difference between the data voltage from the gate electrode G and the driving voltage from the drain electrode D. Meanwhile, a passivation layer 30 is formed on the gate insulating layer 20, the pixel electrode 160 and the common voltage line 140. The passivation layer 30 may include silicon nitride (SiNₓ) and/or an organic layer. Further, the passivation layer 30 is formed with the contact hole 141 for exposing the common voltage line 140.

The pixel electrode 160 is an anode that is electrically connected with the driving transistor 150 and provides the organic emission layer 180 with positively-charged holes. In the top-emission type display device, the pixel electrode 160 providing the holes is typically made of an opaque metal such as nickel (Ni), chrome (Cr) or the like. The pixel electrode 160 preferably includes metal of a high work function to smoothly inject the holes. In some embodiments, the pixel electrode 160 includes a transparent conductive material like the common electrode 190. In these embodiments, light can exit the device from opposite surfaces of the insulating substrate 10 unlike in the present embodiment, in which light exits primarily from one surface of the insulating substrate 10.

Between the pixels is formed an organic insulating layer 40. The organic insulating layer 40 prevents a short-circuit between the pixel electrodes 160 by electrically separating the pixels from each other. Advantageously, the organic insulating layer 40 has a resistance that is lower than that of an inorganic insulating layer. The organic insulating layer 40 is formed with the contact hole 141 through which the common voltage line 140 is exposed. Here, the contact hole 141 is formed throughout the organic insulating layer 40 and the passivation layer 30.

The deposition preventing column 170 is formed on the common voltage line 140 exposed through the contact hole 141, and has an upper width 171 larger than its lower width 173. Preferably, the deposition preventing column 170 has a height d4 that is between about 0.5 μm and about 30 μm. According to an embodiment of the present invention, the deposition preventing column 170 is formed by applying lithography with a negative photoresist material, so that the photoresist layer is formed on the insulating substrate 10 as the deposition preventing column 170 after the lithography.

According to an embodiment of the present invention, the deposition preventing column 170 has a rounded rectangular cross section when sliced in a direction parallel to surface of the insulating substrate 10 on which layers are deposited, and a trapezoidal cross section when sliced in a direction perpendicular to the same surface of the insulating substrate 10. The cross section of the deposition preventing column 170 when sliced parallel to the surface of the insulating substrate 10 may vary according to the thickness of the common voltage line 140 and the density of the deposition preventing column 170.

Because the deposition preventing column 170 has the lower width 173 smaller than the contact hole 141 and the upper width 171 larger than the contact hole 141, the common voltage line 140 exposed through the contact hole 141 is covered by the upper width 171 of the deposition preventing column 170. In the cross-section of the display device taken along the line II-II, a diameter d3 of the contact hole 141 formed in the common voltage line 140 is larger than a diameter d2 of the lower width 173 of the deposition preventing column 170 contacting the common voltage line 140 and smaller than a diameter d1 of the upper width 171 of the deposition preventing column 170. Preferably, three rectangular sections corresponding to the lower width 173, the upper width 171 and the contact hole 141 are coaxially formed.

A lateral of the deposition preventing column 170 between the upper width 171 and the lower width 173 is inclined toward the common voltage line 140. Here, an angle θ between the lateral of the deposition preventing column 170 and the common voltage line 140 is an acute angle. The angle θ is variable according to the ratio of the lower width 173, the upper width 171 and the width of the common voltage line 140 exposed through the contact hole 141. Preferably, the angle θ ranges from about 30° to about 75°.

Thus, the contact hole 141 formed in the common voltage line 140 is covered by the deposition preventing column 170. This way, the organic emission layer 180 can be deposited on the entire surface by using the open mask, with the exception of the emission layers for representing colors.

In the case where an organic layer is deposited with small molecules by an evaporation method, an organic material lands on the insulating substrate 10 without being diffused in all directions. Thus, no organic material lands on the exposed portion of the common voltage line 140, blocked by the deposition preventing column 170. Therefore, the open mask can be used instead of the shadow mask when the organic layer is deposited, except for the emission layer. If the shadow mask is used, the shadow mask is moved from pixel to pixel to form the organic layer, necessitating a plurality of processes for aligning the shadow mask and the insulating substrate 10. Hence, use of the shadow mask complicates a fabricating process and increases material consumption. The deposition preventing column 170 facilitates the formation of the organic layer and decreases the material consumption.

The invention is not limited to the shown position and the illustrated number of deposition preventing columns 170. Because the deposition preventing column 170 is formed by one process independently of its number, the number of deposition preventing columns 170 is properly determined to smoothly supply the common voltage.

The organic emission layer 180 is formed without being deposited on the portion corresponding to the common voltage line 140 exposed through the contact hole 141. In the organic emission layer 180, the hole and the electrons are combined in response to a voltage applied from the driving transistor 150, thereby creating an exciton. The exciton emits light having an intensity that corresponds to the energy level difference between the hole and the electron upon transitioning from an excited state to a ground state in a process that is sometimes referred to as emission recombination of the exciton. The emission layer is formed on the pixel electrode 160 by stacking different materials for emitting red, green and blue light. When the emission layer is formed, the shadow mask that is patterned according to colors and pixels is used to prevent color mixture.

The display device includes the common electrode 190 formed on substantially an entire surface of the device. The current from the organic emission layer 180 is discharged through the common electrode 190. The common electrode 190 is formed on a portion corresponding to the common voltage line 140 exposed through the contact hole 141, and the common voltage applied to the common voltage line 140 is supplied to the common electrode 190. Therefore, the common voltage applied to the common electrode 190 is supplied without much impediment and the brightness of the display device is enhanced.

In the top emission type display device, light is emitted through the common electrode 190 so that the common electrode 190 is made of a transparent conductive material such as indium tin oxide (ITO) or indium zinc oxide (IZO). Further, the common electrode 190 may be formed by a laminating metal such as nickel (Ni) or chromium (Cr). Also, the common electrode 190 may be formed by combining ITO or IZO with a metal such as Ni, Cr or the like in various combinations. Here, the common electrode 190 is employed as a cathode for supplying electrons to the organic emission layer 180.

Below, a method of fabricating a display device according to an embodiment of the present invention will be described with reference to FIG. 3.

First, as shown in FIG. 3A, the common voltage line 140 and the driving thin film transistor 150 are formed on the insulating substrate 10. The driving thin film transistor 150 has a channel made of amorphous silicon, which can be fabricated by a well-known method. After forming the driving thin film transistor 150, the passivation layer 30 is formed on the driving thin film transistor 150. At this time, a chemical vapor deposition (CVD) method can be used in the case where the passivation layer 30 is made of silicon nitride. Then, photolithography is applied to the passivation layer 30, thereby forming the contact holes 157 and 141 through which a source electrode 155 and the common electrode 140 are exposed, respectively. After forming the contact hole 157, the pixel electrode 160 is formed to be connected with the source electrode 155 through the contact hole 157. The pixel electrode 160 can be formed by using a sputtering method to deposit metal and patterning the deposited metal. Here, the pixel electrode 160 provides the emission layer with the holes.

As shown in FIG. 3B, the organic insulating layer 40 is formed on the passivation layer 30 but not on a part of the pixel electrode 160 and not in the contact hole 141. The organic insulating layer 40 is deposited and patterned by the photolithography, thereby removing any deposits from the contact hole 141 and exposing the common voltage line 140. The contact hole 141 on the common voltage line 140 is provided when the passivation layer 30 and the organic layer 40 are formed. The lithography process is performed twice to form the contact hole 141 through both layers (30, 40).

As shown in FIG. 3C, a negative photoresist 170a is used to form the deposition preventing column 170. In this case, the photoresist 170a is formed on the insulating substrate 10 at a uniform thickness. In the present embodiment, the photoresist 170a is of a negative type, so that the exposed region does not react with a developer. Then, a mask 200 having a pattern for the deposition preventing column 170 is placed on and aligned with the photoresist 170a, and the photoresist 170a is exposed to radiation.

FIG. 3D shows the photoresist 170a after the exposure and development. Here, the remaining photoresist 170a is used as the deposition preventing column 170. Because the angle θ between the deposition preventing column 170 and the common voltage line 140 is determined according to the exposure and the development, the sides of the deposition preventing column 170 can be inclined at a desired angle by controlling the exposure time.

After forming the deposition preventing column 170, an open mask 210 is used to pattern a hole injection layer 181 and a hole transport layer 182 in sequence. As shown in FIG. 3E, the open mask 210 is closed above the deposition preventing column 170. When using small molecules, the hole injection layer 181 and the hole transport layer 182 are formed by an evaporation method. When the evaporation method is used, organic material transfers through the openings in the open mask 210 but generally do not diffuse through the closed portions. Thus, the hole injection layer 181 and the hole transport layer 182 are not deposited in the contact hole 141 covered by the deposition preventing column 170.

As shown in FIG. 3F, an emission layer 185 for representing colors is formed on the pixel electrode 160. The shadow mask 220 used in a process of forming the emission layer 185 is formed with an opening in the shadow mask 220 in the area corresponding to a colored pixel, thereby preventing a processing pixel from having an effect on other pixels while depositing the emission material for a certain color. To deposit the emission material for one color on the insulating substrate 10, the shadow mask 220 is realigned every time when it moves. Thus, the process using the shadow mask 220 is more complicated and difficult than that using the open mask 200. The foregoing respective processes are performed every time when the different emission materials for the red, green and blue (or cyan, magenta and yellow) are deposited, thereby forming the emission layer 185.

FIG. 3G shows a process of forming an electron transport layer 186 and an electron injection layer 187 on the emission layer 185. The open mask 10 is used for depositing the electron transport layer 186 and the electron injection layer 187 on the insulating substrate 10, like that of FIG. 3E for the hole injection layer 181 and the hole transport layer 182.

The purpose of the hole injection layer 181, the hole transport layer 182, the electron transport layer 186 and the electron injection layer 187 are is to facilitate light emission from the emission layer 185 and the transport of the hole and the electron into the emission layer 185. Thus, it is not the case that all of these layers are necessary. Depending on the embodiment, none, some or all of the hole injection layer 181, the hole transport layer 182, the electron transport layer 186 and the electron injection layer 187 may be used.

Last, the common electrode 190 is formed on the surface of the insulating substrate 10. Here, the method of depositing the common electrode 190 can be selected based on whether the material for the common electrode diffuses in all directions during the deposition on the insulating substrate 10.

When a sputtering method is used as one of a physical vapor deposition (PVD) method for depositing the common electrode 190, a common electrode material 190a diffuses in all directions of the insulating substrate 10 (refer to FIG. 3H). As a result, the common electrode material 190a is likely to be formed on a portion where the organic emission layer 180 is not formed. According to the sputtering method, a plasma state is generated while a vacuum chamber is filled with argon gas, and then an accelerated ion in the plasma state collides with the material to be sputtered. The collision allows material particles to escape from the material. As the material particles are attached to the insulating substrate 10, the common electrode 190 is formed.

Besides the physical vapor deposition (PVD), an atomic layer chemical vapor deposition (ALCVD) method can be used for forming the common electrode 190. In this case, the common electrode material for chemical combination is deposited on the insulating substrate 10 in all directions, so that the common electrode 190 can be formed on a portion where the common voltage line 140 is exposed.

Alternatively, the common electrode 190 can be formed by an evaporation method. In particular, an electron beam evaporation method has been widely used as the evaporation method of choice. In the electron beam evaporation method, high voltage is applied to a filament, and electron beam emitted from the filament is used in depositing the metal material. The electron beam emitted from the filament has an energy level that is high enough to partially fuse and evaporate the metal material. As the evaporated metal atoms are attached to the insulating substrate 10, the common electrode 190 is formed. The electron beam evaporation method has advantages such as fast deposition speed and easy deposition of high fusion point metal.

In the case where the common electrode 190 is formed by an evaporation method such as the electron beam evaporation method, the metal atoms reach the insulating substrate 10 from an orthogonal direction without and do not diffuse in all directions during their deposition on the insulating substrate 10. In this case, the common electrode 190 is not likely to be formed normally on the part of the common voltage line 140 that is covered by the deposition preventing column 170. Thus, the insulating substrate 10 is inclined while performing the deposition process. More specifically, the insulating substrate 10 is inclined at a predetermined angle to the traveling direction of the evaporated metal materials in order to sufficiently deposit the metal material on the portion of the common voltage line 140 that is covered by the deposition preventing column 170.

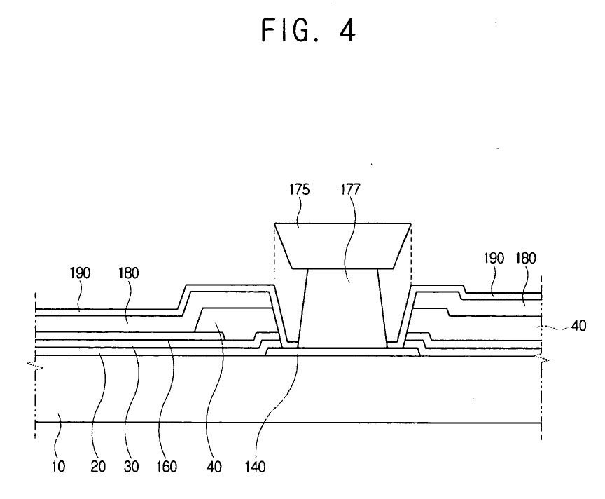

FIG. 4 is a sectional view of a display device according to a second embodiment of the present invention. As shown therein, the deposition preventing column 170 includes two layers of an upper insulating layer 175 and a lower insulating layer 177. The upper insulating layer 175 and the lower insulating layer 177 schematically have a trapezoidal cross section like the deposition preventing column 170 shown in FIG. 1, but is divided into two layers. Here, the upper insulating layer 175 becomes wider as it gets farther away from the insulating substrate 10, and the lower insulating layer 177 becomes narrower as it gets farther away from the insulating substrate 10. The widest part of the upper insulating layer 175 is wider than the widest part of the lower insulating layer 177. The insulating layers 175 and 177 are made of insulating materials having different etch rates, and each layer may include one of SiO₂, SiNx and SiON.

A process of fabricating the deposition preventing column 170 will now be described. First, insulating materials having different etch rates are deposited, and a photoresist is exposed and developed, thereby forming a photoresist layer. Then, the developed photoresist layer is etched to form the two insulating layers 175 and 177. Because the insulating material for the lower insulating layer 177 has an etch rate higher than that for the upper insulating layer 177, the lower and upper insulating layers 175 and 177 are etched differently with the same etchant, resulting in two inverted trapezoidal columns. According to the second embodiment of the present invention, the shape of the deposition preventing column 170 is varied according to the properties and the etch rates of the insulating materials against the etchant.

It should be understood that the insulating layers 175 and 177 are not limited to the two layers as described above, and may be formed in more layers that are combinations of materials having various etch rates.

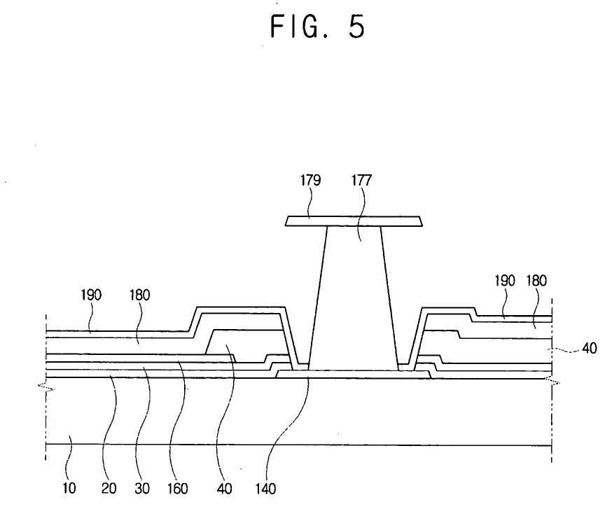

FIG. 5 is a sectional view of a display device according to a third embodiment of the present invention. The deposition preventing column 170 according to the third embodiment of the present invention is similar to that of the second embodiment in that it is formed in two layers, but different in that the upper layer 179 is made of a metal instead of the insulating material.

The metal layer 179 can include a material selected from a group of molybdenum (Mo), chromium (Cr), aluminum (Al), silver (Ag), copper (Cu), molybdenum-tungsten alloy (MoW) and aluminum-neodymium alloy (AlNd). Further, the metal layer 179 may be achieved by a combination of various metals. Here, the etch rate of the metal layer 179 is lower than that of the insulating layer 177, so that the metal layer 179 is preferably placed on the insulating layer 177 in order to have the inverted trapezoidal section of the deposition preventing column 170.

The third embodiment is similar to the second embodiment in the method of forming the deposition preventing column 170, but different from the second embodiment in that the insulating layer and the metal layer are successively deposited before forming the photoresist layer. When the metal layer 179 is used for the deposition preventing column 170, the etch rate of the metal is generally lower than that of the insulating material, so that there is no complicated process for considering the etch rate and the inverted trapezoidal section is also easily formed.

As described above, the present invention provides a display device which can simplify a fabricating process and reduce production cost.

Further, the present invention provides a fabricating method for a display device that is simpler and most cost-efficient than the currently used fabricating process.

Although embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A display device comprising:
an insulating substrate;
a common voltage line formed on the insulating substrate;
an insulating layer provided on the common voltage line;
a contact hole extending through the insulating layer to the common voltage line;
a deposition preventing column contacting a portion of the common voltage line in the contact hole, wherein the width of the deposition preventing column changes with distance from the insulating substrate; and
a common electrode connected to the common voltage line.

2. The display device according to claim 1, wherein the widest portion of the deposition preventing column is wider than the width of the common voltage line at the bottom of the contact hole and the contact hole is covered by the deposition preventing column.

3. The display device according to claim 1, wherein the widest portion of the deposition preventing column is the portion of the deposition preventing column that is farthest from the insulating substrate.

4. The display device according to claim 1, wherein a sidewall of the deposition preventing column forms an acute angle with the common voltage line.

5. The display device according to claim 4, wherein the acute angle is between about 30° and about 75°.

6. The display device according to claim 1, wherein the deposition preventing column has a height between about 0.5 and about 30 μm.

7. The display device according to claim 1, wherein the deposition preventing column comprises at least two layers.

8. The display device according to claim 7, wherein the deposition preventing column comprises at least two insulating layers having different etch rates.

9. The display device according to claim 8, wherein at least one of the insulating layers of the deposition preventing column comprises at least one of silicon oxide (SiO₂), silicon nitride (SiNx) and silicon oxynitride (SiON).

10. The display device according to claim 7, wherein the deposition preventing column comprises two layers.

11. The display device according to claim 7, wherein one of the insulating layers of the deposition preventing column comprises a metal.

12. The display device according to claim 11, wherein the metal layer comprises at least one of molybdenum (Mo), chromium (Cr), aluminum (Al), silver (Ag), copper (Cu), molybdenum-tungsten alloy (MoW) and aluminum-neodymium alloy (AlNd).

13. The display device according to claim 1, wherein the common electrode comprises at least one of indium tin oxide (ITO), indium zinc oxide (IZO), nickel (Ni) and chromium (Cr).

14. The display device according to claim 1, further comprising:
a thin film transistor;
a pixel electrode electrically connected to the thin film transistor; and
an emission layer formed on the pixel electrode,
wherein the emission layer emits light through the common electrode.

15. A method of fabricating a display device, comprising:
forming a common voltage line on an insulating substrate;
forming a first insulating layer on the common voltage line;
forming a contact hole through the first insulating layer, the contact hole extending to the common voltage line;
forming an deposition preventing column that contacts a portion of the common voltage line, wherein the width of the deposition preventing column changes with distance from the insulating substrate; and
forming a common electrode connected to the exposed common voltage line.

16. The method according to claim 15, wherein the deposition preventing column is formed by exposing and developing a negative photoresist.

17. The method according to claim 15, wherein the forming of the deposition preventing column comprises:
forming a plurality of second insulating layers having different etch rates;
forming a photoresist layer on the second insulating layers; and
removing a portion of the second insulating layers by etching.

18. The method according to claim 15, wherein the forming of the deposition preventing column comprises:
forming a second insulating layer and a metal layer successively;
forming a photoresist layer on the metal layer; and
removing a portion of the second insulating layer and the metal layer by etching.

19. The method according to claim 15, wherein the common electrode is formed by a sputtering method.

20. The method according to claim 15, wherein the common electrode is formed by an evaporation method performed with the insulating substrate inclined to form a predetermined angle with a primary direction in which the depositing molecules travel.

21. The method according to claim 15, further comprising:
forming a thin film transistor;
forming a pixel electrode electrically connected to the thin film transistor and positioned on the insulating layer; and
forming an emission layer on the pixel electrode.

22. The method according to claim 21, wherein the emission layer is formed by using a shadow mask.

23. The method according to claim 21, further comprising:
forming at least one of a hole injection layer and a hole transport layer on the pixel electrode; and
forming at least one of an electron transport layer and an electron injection layer on the emission layer,
wherein the hole injection layer, the hole transport layer, the electron transport layer and the electron injection layer are formed by using an open mask.
